(19) United States
(12) Patent Application Publication
(10) Pub. No.: US 2023/0215905 A1
(43) Pub. Date: Jul. 6, 2023

(54) DISPLAY DEVICE

(71) Applicant: LG Display Co., Ltd., Seoul (KR)

(72) Inventors: Aram SOHN, Seongnam-si (KR); DaeHeung LEE, Paju-si (KR); JuHyuk KIM, Goyang-si (KR); Byonghoo KIM, Paju-si (KR); Sumin LEE, Seoul (KR)

(21) Appl. No.: 18/063,643

(22) Filed: Dec. 8, 2022

(30) Foreign Application Priority Data
Dec. 30, 2021 (KR) 10-2021-0192408

(51) Int. Cl. H01L 27/15; H01L 33/00; H01L 33/40; H01L 33/46; H01L 33/56; H01L 33/50

(52) U.S. Cl. CPC H01L 27/156; H01L 33/40; H01L 33/46; H01L 33/56; H01L 33/0083; H01L 33/0095; H01L 33/501

(57) ABSTRACT

A display device according to an example embodiment of the present disclosure includes a first substrate including an active area including a plurality of pixels and a non-active area surrounding the active area; a plurality of LEDs disposed in the plurality of pixels on the first substrate; a planarization layer disposed to surround the plurality of LEDs; a bank disposed on the planarization layer and including a black material; a reflection-reducing layer disposed on the bank and having a reflectance varying according to temperature; and a heat dissipation layer disposed on the reflection-reducing layer.

### CROSS-REFERENCE TO RELATED APPLICATIONS

This application claims the benefit of and priority to Korean Patent Application No. 10-2021-0192408 filed on Dec. 30, 2021, in the Republic of Korea, the entire contents of which are hereby expressly incorporated by reference into the present application.

### BACKGROUND

### Technical Field

The present disclosure relates to a display device, and more particularly, to a display device using a light emitting diode (LED).

### Description of the Related Art

Liquid crystal display devices and organic light emitting display devices are widely applied to screens of usual electronic devices, such as mobile phones and laptop computers or the like, due to the advantages of being able to provide high resolution screens and allowing for thinning and weight reduction thereof, and an application range of the display devices is also gradually expanding. However, in liquid crystal display devices and organic light emitting display devices, there is a limitation in reducing a size of a bezel area visible to a user, which is an area where an image is not displayed in the display device. In particular, since it is infeasible to implement an extra-large screen as a single panel, when a plurality of liquid crystal display panels or a plurality of organic light emitting display panels are disposed in a type of tile shape to implement an extra-large screen, a defect in which a bezel area between adjacent panels is visible by a user can be caused.

As an alternative to this, a display device including LEDs has been proposed. Since the LED is formed of an inorganic material rather than an organic material, it has excellent reliability and has a longer lifespan compared to a liquid crystal display device or an organic light emitting display device. In addition, the LED is an element that is suitable for being applied to an extra-large screen because it has not only a fast-lighting speed, but also has low power consumption and excellent stability due to strong impact resistance, and can display high luminance images.

### BRIEF SUMMARY

Accordingly, an aspect of the present disclosure is to provide a display device in which color loss defects in a bank are solved or reduced in number.

Another aspect of the present disclosure is to provide a display device capable of preventing or reducing cracks and a color loss phenomenon due to high heat by using a heat dissipation layer and easily dissipating heat generated from an LED.

Another aspect of the present disclosure is to provide a display device in which external light reflection is reduced.

Technical benefits of the present disclosure are not limited to the above-mentioned technical benefits, and other technical benefits, which are not mentioned above, can be clearly understood by those skilled in the art from the following descriptions.

A display device according to an example embodiment of the present disclosure may include a first substrate including an active area including a plurality of pixels and a non-active area adjacent the active area; a plurality of light-emitting diodes (LEDs) disposed in the plurality of pixels on the first substrate; a planarization layer disposed to surround the plurality of LEDs on at least four sides; a bank disposed on the planarization layer and including a black material; a reflection-reducing layer disposed on the bank and having a reflectance that varies according to temperature thereof; and a heat dissipation layer disposed on the reflection-reducing layer.

In accordance with various embodiments, a display device includes a substrate, a plurality of pixels on the substrate, a plurality of light-emitting diodes disposed in the plurality of pixels, a planarization layer adjacent to the plurality of light-emitting diodes, a bank disposed on the planarization layer, a first layer disposed on the bank and having reflectance that is lower at a driving temperature of the display device than at room temperature, and a second layer disposed on the first layer, the second layer including a vertically aligned carbon nanotube layer doped with metal oxide particles.

In accordance with various embodiments, a display device includes a substrate, a plurality of pixels on the substrate, a plurality of light-emitting diodes disposed in the plurality of pixels, a planarization layer adjacent to the plurality of light-emitting diodes, a bank disposed on the planarization layer, the bank absorbing light in a range of about 380 nanometers to about 700 nanometers, and a vertically aligned carbon nanotube layer disposed on the bank.

Other detailed matters of the example embodiments are included in the detailed description and the drawings.

According to the present disclosure, color loss defects in a bank can be solved.

According to the present disclosure, cracks and a color loss phenomenon due to high heat can be prevented and heat generated from an LED can be easily dissipated.

According to the present disclosure, external light reflection can be reduced.

The effects according to the present disclosure are not limited to the contents exemplified above, and more various effects are included in the present specification.

### BRIEF DESCRIPTION OF THE SEVERAL VIEWS OF THE DRAWINGS

FIG. 1 is a schematic plan view of a display device according to an example embodiment of present disclosure.

FIG. 2 is a cross-sectional view of a non-active area of the display device according to an example embodiment of present disclosure.

FIG. 3 is a cross-sectional view of an active area of the display device according to an example embodiment of present disclosure.

FIG. 4 is a graph for external light reflectances of display devices according to Comparative Example and Example of the present disclosure.

### DETAILED DESCRIPTION

Advantages and characteristics of the present disclosure and a method of achieving the advantages and characteristics will be clear by referring to example embodiments described below in detail together with the accompanying drawings. However, the present disclosure is not limited to the example embodiments disclosed herein but will be implemented in various forms. The example embodiments are provided by way of example only so that those skilled in the art can fully understand the disclosures of the present disclosure and the scope of the present disclosure.

The shapes, sizes, ratios, angles, numbers, and the like illustrated in the accompanying drawings for describing the example embodiments of the present disclosure are merely examples, and the present disclosure is not limited thereto. Like reference numerals generally denote like elements throughout the specification. Further, in the following description of the present disclosure, a detailed explanation of known related technologies may be omitted to avoid unnecessarily obscuring the subject matter of the present disclosure. The terms such as “including,” “having,” and “consist of” used herein are generally intended to allow other components to be added unless the terms are used with the term “only”. Any references to singular may include plural unless expressly stated otherwise.

Components are interpreted to include an ordinary error range even if not expressly stated.

When the position relation between two parts is described using the terms such as “on,” “above,” “below,” and “next,” one or more parts may be positioned between the two parts unless the terms are used with the term “immediately” or “directly.”

When an element or layer is disposed “on” another element or layer, another layer or another element may be interposed directly on the other element or therebetween.

Although the terms “first,” “second,” and the like are used for describing various components, these components are not confined by these terms. These terms are merely used for distinguishing one component from the other components. Therefore, a first component to be mentioned below may be a second component in a technical concept of the present disclosure.

Like reference numerals generally denote like elements throughout the specification.

A size and a thickness of each component illustrated in the drawing are illustrated for convenience of description, and the present disclosure is not limited to the size and the thickness of the component illustrated.

The features of various embodiments of the present disclosure can be partially or entirely adhered to or combined with each other and can be interlocked and operated in technically various ways, and the embodiments can be carried out independently of or in association with each other.

Hereinafter, a display device according to example embodiments of the present disclosure will be described in detail with reference to accompanying drawings.

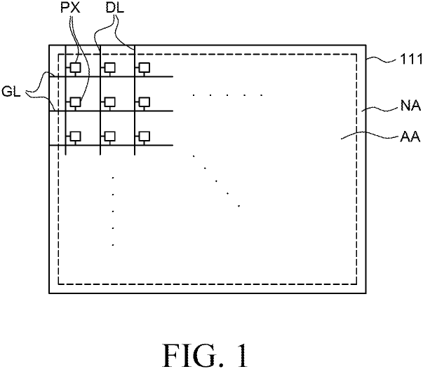

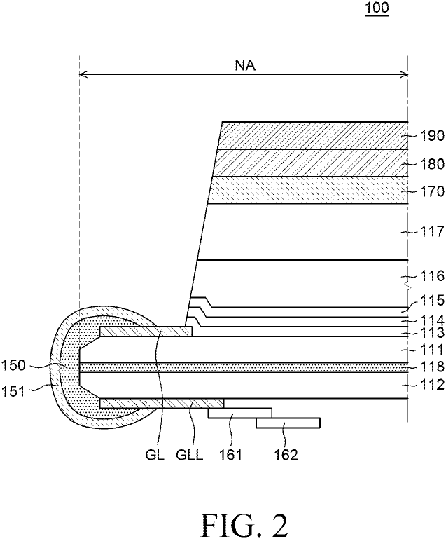

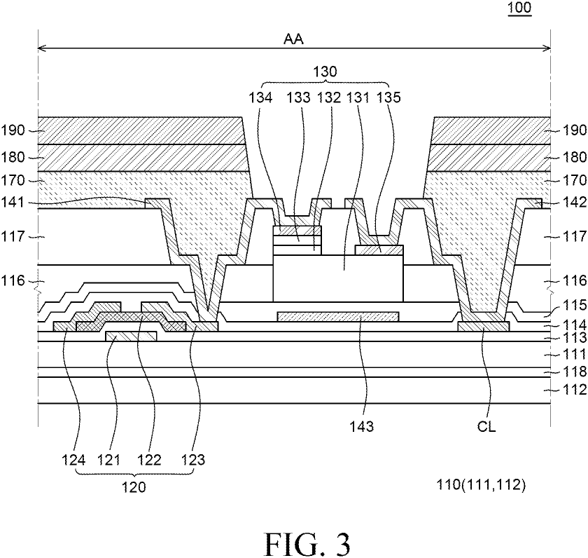

FIG. 1 is a schematic plan view of a display device according to an example embodiment of present disclosure. FIG. 2 is a cross-sectional view of a non-active area of the display device according to an example exemplary embodiment of present disclosure. FIG. 3 is a cross-sectional view of an active area of the display device according to an example embodiment of present disclosure.

Referring to FIGS. 1 to 3, a display device 100 includes a substrate 110, thin film transistors 120, LEDs 130, a common line CL, a reflective layer 143, gate lines GL, and gate link lines GLL, data lines DL, data link lines (not shown), side lines 150, an insulating layer 151, a first planarization layer 116, a second planarization layer 117, a bank 170, a reflection-reducing layer 180, and a heat dissipation layer 190.

Referring to FIG. 1, an active area AA and a non-active area NA adjacent the active area AA may be included in the substrate 110. The active area AA is an area where an image is actually displayed in the display device 100, and the LED 130 and the thin film transistor 120 for driving the LED 130 and the like, which will be described later, may be disposed in the active area AA.

The non-active area NA is an area where an image is not displayed and may be an area surrounding the active area AA. Various lines, such as the gate line GL and the data line DL that are connected to the LED 130 and the thin film transistor 120 disposed in the active area AA, and the like, may be disposed in the non-active area NA. Although it is described herein that the active area AA and the non-active area NA are included in a first substrate 111, the first substrate 111 may be have no non-active area NA, but the present disclosure is not limited thereto. That is, when a tiling display is implemented using the display device 100 according to an example embodiment of the present disclosure, since a distance between the LED 130 at an outermost position of one panel and the LED 130 at an outermost position of another panel adjacent thereto may be implemented to be equal to a distance between LEDs 130 in one panel, a zero bezel in which there is substantially no bezel area may be implemented. Accordingly, it may be described that only the active area AA is included in the substrate 110 and the non-active area NA is omitted from the substrate 110.

A plurality of pixels PX are disposed in the active area AA of the substrate 111. Each of the plurality of pixels PX is an individual unit or structure emitting light, and the plurality of pixels PX may include a red pixel, a green pixel, and a blue pixel, but the present disclosure is not limited thereto. The LED 130 and the thin film transistor 120 are disposed in each of the plurality of pixels PX. A more detailed description of the LED 130 and the thin film transistor 120 will be described later with reference to FIG. 3.

The substrate 110 includes the first substrate 111 and a second substrate 112.

The first substrate 111 is a substrate that supports components disposed on the display device 100, and may be an insulating substrate. For example, the first substrate 111 may be formed of glass or resin or the like. Also, the first substrate 111 may be formed to include a polymer or plastic. For example, the first substrate 111 may be formed of a plastic material having flexibility.

The second substrate 112 is a substrate that supports components disposed in a lower portion of the display device 100, and may be an insulating substrate. For example, the second substrate 112 may be formed of glass or resin or the like. Also, the second substrate 112 may be formed to include a polymer or plastic. For example, the second substrate 112 may be formed of a plastic material having flexibility.

The first substrate 111 and the second substrate 112 are bonded through a bonding layer 118. The bonding layer 118 may be formed of a material capable of being cured through various curing methods to bond the first substrate 111 and the second substrate 112 to each other. The bonding layer 118 may be disposed over an entire area between the first substrate 111 and the second substrate 112, or may be disposed only on a partial area therebetween.

Referring to FIGS. 1 and 2, various signal lines such as the gate line GL and the data line DL that are connected to the LED 130 and the thin film transistor 120 disposed in the active area AA, and the like may be disposed in the non-active area NA on the first substrate 111.

Various signal link lines such as a plurality of the gate link lines GLL and a plurality of the data link lines may be disposed in the non-active area NA under the second substrate 112. The plurality of gate link lines GLL may be lines for connecting a gate driver and the plurality of gate lines GL formed on an upper surface of the first substrate 111. The plurality of data link lines may be lines for connecting a data driver and the plurality of data lines DL formed on the upper surface of the first substrate 111.

A flexible film 161 is disposed on one ends of the plurality of data link lines. The flexible film 161 is electrically connected to the one ends of the plurality of data link lines. The flexible film 161 is a film for supplying signals to the plurality of pixels PX in the active area AA by disposing various components on a flexible base film. The flexible film 161 may be disposed in the non-active area NA of the second substrate 112 and supply a data voltage or the like to the plurality of pixels PX in the active area AA.

On the flexible film 161, driver ICs such as a gate driver IC and a data driver IC may be disposed. The driver IC is a component that processes data for displaying an image and a driving signal for processing it. The driver IC may be disposed in a method such as a chip-on-glass (COG), chip-on-film (COF), or tape carrier package (TCP) method according to a mounting method. In the present disclosure, for convenience of description, the driver IC is described as being in a chip-on-film method in which it is mounted on the flexible film 161, but the present disclosure is not limited thereto.

A printed circuit board 162 is connected to the flexible film 161. The printed circuit board 162 is a component that supplies a signal to the driver IC. Various components for supplying various driving signals such as a driving signal, a data voltage and the like to the driver IC may be disposed on the printed circuit board 162.

The side line 150 is disposed on side surfaces of the first substrate 111 and the second substrate 112. The side line 150 is disposed to connect the signal line and the signal link line. For example, the side line 150 may electrically connect the gate line GL and the gate link line GLL, and electrically connect the data line DL and the data link line. The side line 150 may be formed by a method of printing a pad on the substrate 110 in a state in which a conductive paste is applied to the pad. In this case, the conductive paste may be a state in which a material having high electrical conductivity, such as silver (Ag) or copper (Cu), is prepared in a form of a paste, and the side line 150 may be a line in which the conductive paste is cured.

The insulating layer 151 including a black material is formed to cover the side line 150. The insulating layer 151 including a black material may be formed to cover the side line 150 on the upper surface of the first substrate 111, the side surfaces of the first substrate 111 and the second substrate 112, and a lower surface of the second substrate 112. When the side line 150 is formed of a metallic material, a defect in which external light may be reflected from the side line 150 or light emitted from the LED 130 may be reflected by a plurality of the side line 150 and be recognized by a user. Accordingly, the insulating layer 151 formed of a black material is disposed to cover the side line 150, so that the defect described above may be solved.

Referring to FIGS. 2 and 3, the thin film transistor 120 is formed on the first substrate 111. Specifically, a gate electrode 121 is disposed on the substrate 111, and an active layer 122 is disposed on the gate electrode 121. A gate insulating layer 113 for insulating the gate electrode 121 and the active layer 122 is disposed between the gate electrode 121 and the active layer 122. A source electrode 123 and a drain electrode 124 are disposed on the active layer 122, and a passivation layer 114 for protecting the thin film transistor 120 is disposed on the source electrode 123 and the drain electrode 124. A hole may be formed in the passivation layer 114 to expose a portion of the source electrode 123 of the thin film transistor 120. However, the passivation layer 114 may be omitted in some embodiments.

The common line CL is disposed on the gate insulating layer 113. The common line CL is a line for applying a common voltage to the LED 130, and may be disposed to be spaced apart from the gate line GL or the data line DL. Also, the common line CL may extend in a direction the same as the gate line GL or the data line DL extends. The common line CL may be formed of the same material as the source electrode 123 and the drain electrode 124, but is not limited thereto and may be formed of the same material as the gate electrode 121. The passivation layer 114 is formed on the common line CL, but a hole exposing a portion of the common line CL may be formed in the passivation layer 114.

The reflective layer 143 is disposed on the passivation layer 114. The reflective layer 143 is a layer for reflecting light that is emitted toward the first substrate 111 among the light emitted from the LED 130, upwardly of the display device 100, to thereby emit the light to an outside of the display device 100. The reflective layer 143 may be formed of a metallic material having a high reflectance.

An adhesive layer 115 is disposed on the reflective layer 143. The adhesive layer 115 is an adhesive layer 115 for bonding the LED 130 onto the reflective layer 143, and may insulate the reflective layer 143 formed of a metallic material from the LED 130. The adhesive layer 115 may be formed of a heat-curable material or a light-curable material, but is not limited thereto.

The LED 130 is disposed on the adhesive layer 115 to overlap the reflective layer 143. The LED 130 includes an n-type layer 131, an active layer 132, a p-type layer 133, an n-electrode 135, and a p-electrode 134. Hereinafter, it will be described that the LED 130 having a lateral structure is used as the LED 130, but the structure of the LED 130 is not limited thereto, and a vertical form or a flip form may be used as the structure of the LED 130. The LED 130 may have a micro-size (a chip size of 100 µm or less) or a mini-size (a chip size of several hundred µm).

An example stacked structure of the LED 130 is as follows. The n-type layer 131 may be formed by implanting n-type impurities into gallium nitride (GaN). The active layer 132 is disposed on the n-type layer 131. The active layer 132 is an emission layer emitting light from the LED 130 and may be formed of a nitride semiconductor, for example, indium gallium nitride (InGaN). The p-type layer 133 is disposed on the active layer 132. The p-type layer 133 may be formed by implanting p-type impurities into gallium nitride. However, materials constituting the n-type layer 131, the active layer 132, and the p-type layer 133 are not limited thereto.

As described above, the LED 130 may be formed by sequentially stacking the n-type layer 131, the active layer 132, and the p-type layer 133 and then, etching a predetermined or selected portion thereof to form the n-electrode 135 and the p-electrode 134. In this case, the predetermined or selected portion is a space for separating the n-electrode 135 and the p-electrode 134, and the predetermined or selected portion may be etched to expose a portion of the n-type layer 131. In other words, a surface of the LED 130 on which the n-electrode 135 and the p-electrode 134 are to be disposed may have different height levels rather than a planarized surface.

As described above, the n-electrode 135 may be disposed on the n-type layer 131 that is exposed. The n-electrode 135 may be formed of a conductive material, for example, a transparent conductive oxide. Meanwhile, the p-electrode 134 may be disposed on a non-etched area, that is, the p-type layer 133. The p-electrode 134 may also be formed of a conductive material, for example, a transparent conductive oxide. Also, the p-electrode 134 may be formed of the same material as the n-electrode 135.

As described above, in a state in which the n-type layer 131, the active layer 132, the p-type layer 133, the n-electrode 135, and the p-electrode 134 are formed, the LED 130 may be disposed such that the n-type layer 131 is adjacent to the reflective layer 143 rather than the n-electrode 135 and the p-electrode 134.

The first planarization layer 116 and the second planarization layer 117 are positioned on the upper surface of the first substrate 111. The first planarization layer 116 planarizes an upper portion of the thin film transistor 120. The first planarization layer 116 may planarize the upper portion of the thin film transistor 120 in an area excluding an area where the LED 130 is disposed and a contact hole. The second planarization layer 117 may be disposed on the first planarization layer 116. The second planarization layer 117 may be disposed on the thin film transistor 120 and the LED 130 in areas excluding the contact hole. In this case, the second planarization layer 117 may be formed such that some areas of the p-electrode 134 and the n-electrode 135 of the LED 130 are opened. FIGS. 2 and 3 illustrate that two planarization layers are used in manufacturing the display device 100, it is not necessarily to form a plurality of the planarization layers 116 and 117, and the planarization layers 116 and 117 may be formed of a single planarization layer. In addition, the planarization layers 116 and 117 may be composed of three or more layers.

The first planarization layer 116 and the second planarization layer 117 may serve to fix a position of the LED 130. That is, while the first planarization layer 116 and the second planarization layer 117 are formed after positioning the LED 130, they are disposed to surround the LED 130 and may be completely in close contact with the LED 130. Unlike a conventional method in which a receiving space such as a cup or a hole is provided in the planarization layer and then, an LED is transferred thereto, a structure in which the planarization layer is stacked after the LED is placed may allow for the LED to be more stably fixed in place. The term, “surround” is used herein in the broadest sense to include the meaning of partially (e.g., laterally) surround or fully surround. For example, the second planarization layer 117 may surround the LED 130 on four lateral sides, i.e., front, back, right and left, as shown in FIG. 3. The second planarization layer 117 may partially surround the LED 130 in the vertical plane, for example, due to extensions thereof that overlap the upper surface of the p-electrode 134. The meaning of “surround” does not required that six or more surfaces (e.g., including top and bottom surfaces) be surrounded. In some embodiments, the LEDs 130 have a rectangular (e.g., square) profile, and at least four surfaces thereof are surrounded. For LEDs 130 having circular profile, “surround” may mean wrapping at least half way around the sidewall of the circular LED.

In addition, the first planarization layer 116 and the second planarization layer 117 may facilitate a connection between the source electrode 123 and the p-electrode 134. As illustrated in FIG. 3, a first connection electrode 141 may be continued with a gentle slope through the planarization layers 116 and 117 between the source electrode 123 and the p-electrode 134. If there is no gentle slope of the planarization layers 116 and 117, a possibility of disconnection of the first connection electrode 141 increases because a portion between the source electrode 123 and the p-electrode 134 is connected through a steep slope of a side wall of the LED 130. Accordingly, connection stability between the source electrode 123 and the p-electrode 134 is increased through the planarization layers 116 and 117.

A value of existence of these planarization layers 116 and 117 is equally applied to a connection between the common line CL and the n-electrode 135. The first planarization layer 116 and the second planarization layer 117 may be formed at one time or may be formed by being divided into two parts.

The first connection electrode 141 connects the thin film transistor 120 and the p-electrode 134 of the LED 130. The first connection electrode 141 may be in contact with the source electrode 123 of the thin film transistor 120 through contact holes formed in the first planarization layer 116, the second planarization layer 117, the passivation layer 114, and the adhesive layer 115 and may be in contact with the p-electrode 134 of the LED 130 through a contact hole formed in the second planarization layer 117. However, the present disclosure is not limited thereto, and the first connection electrode 141 may be in contact with the drain electrode 124 of the thin film transistor 120 depending on a type of the thin film transistor 120. Also, the first connection electrode 141 may be an anode electrode.

The second connection electrode 142 connects the common line CL and the n-electrode 135 of the LED 130. The second connection electrode 142 is in contact with the common line CL through the contact holes formed in the first planarization layer 116, the second planarization layer 117, the passivation layer 114, and the adhesive layer 115, and is in contact with the n-electrode 135 of the LED 130 through the contact hole formed in the planarization layer 117. Also, the second connection electrode 142 may be a cathode electrode.

Accordingly, when the display device 100 is turned on, different levels of voltage that are applied to each of the source electrode 123 and the common line CL of the thin film transistor 120 are transmitted to the p-electrode 134 and the n-electrode 135 through the first connection electrode 141 and a second connection electrode 142, so that the LED 130 may emit light. In FIG. 3, it is described that the thin film transistor 120 is electrically connected to the p-electrode 134 and the common line CL is electrically connected to the n-electrode 135, but the present disclosure is not limited thereto. The thin film transistor 120 may be electrically connected to the n-electrode 135 and the common line CL may be electrically connected to the p-electrode 134.

The bank 170 is an insulating layer adjacent an emission area and is formed on the second planarization layer 117. In this case, the bank 170 may be disposed to fill the contact holes of the first planarization layer 116 and the second planarization layer 117 that are formed for the connection of the first connection electrode 141 and the second connection electrode 142. The bank 170 may be formed of an organic insulating material, and may be formed of the same material as the first planarization layer 116 or the second planarization layer 117. In addition, the bank 170 may be configured to absorb light by further including a black material in order to prevent a phenomenon in which the light emitted from the LED 130 is transmitted to the pixel PX to cause color mixing and to reduce external light reflection. In some embodiments, the black material is an organic material or an inorganic material. The black material may absorb all or most of light in the visible spectrum, namely, from about 380 nanometers to about 700 nanometers. The bank 170 may be a single layer composed entirely of the black material, or may be a multilayer in which the black material is one layer thereof, such as an uppermost layer thereof.

Meanwhile, in a manufacturing process of the side line as described above, a laser is used to dry a conductive paste. For example, when the side line is formed by pad printing the conductive paste, the side line may be formed by drying the conductive paste using a laser in a lateral direction of the display device. In this laser curing process, as the laser is irradiated onto the bank including the black material, a temperature of the bank rises to 300° C. or higher, and thus, a black color loss defect may occur in the bank. When the color loss defect occurs in the bank, a color mixing phenomenon may occur, external light reflection may be severe, and a color difference may occur with respect to black in the bank. In particular, in a sense that resistance of the side line is reduced in accordance with a use of a high-power laser in the laser curing process, the color loss defect of the bank may be severe as the side line is lowered.

Accordingly, in the display device 100 according to an example embodiment of the present disclosure, the heat dissipation layer 190 is disposed on the bank 170. The heat dissipation layer 190 may include a vertically aligned carbon nanotube (CNT) layer and metal oxide particles doped into the carbon nanotube layer. The heat dissipation layer 190 may aid in dissipating heat, and may be thermally conductive. In some embodiments, thermal conductivity of the heat dissipation layer 190 may be in a range of about 5 W/m·K to about 200 W/m·K, about 10 W/m·K to about 150 W/m·K, about 20 W/m·K to about 100 W/m·K or about 25 W/m·K to about 50 W/m·K. The heat dissipation layer 190 may include one or more materials having thermal conductivity greater than 200 W/m·K in some embodiments.

The carbon nanotube layer of the heat dissipation layer 190 may be a single layer or a double layer. In this case, the carbon nanotube layer may be a vertically aligned single-walled or double-walled carbon nanotube array (VA-SW (DW) CNT Array).

The metal oxide particles of the heat dissipation layer 190 may be metal oxide-based black nanoparticles. The metal oxide particles may be doped into the carbon nanotube layer. The black metal oxide particles may be, for example, black titanium oxide particles or black iron oxide particles, but the present disclosure is not limited thereto. Doping concentration of the metal oxide particles in the heat dissipation layer 190 may be in a range of about 10¹³ cm⁻³ to 10¹⁸ cm⁻³, though other ranges may be used.

Additionally, the heat dissipation layer 190 may further include carbon black particles, a binder, and a photosensitizer. The binder may include an alkali-developable binder or a silicone-based binder, and the photosensitizer may include an oxime-based compound or a benzophenone-based compound.

A metal oxide of the heat dissipation layer 190 may be used together with the carbon black particles. The carbon black particles are a general-purpose material that is widely used as a material for a black matrix, and have a high optical density (OD) of about 4.5/µm. However, the carbon black particles have a large particle size in a micrometer unit. Accordingly, the carbon black particles may be used together with the black metal oxide particles to ensure dispersion stability. Since the black metal oxide particles have a very small particle size in a nanometer unit, they are suitable for being doped into the carbon nanotube layer, and may serve as an auxiliary role for black color that is degraded in the laser irradiation process. In addition, in the case of the black metal oxide particles, there is little change in properties due to heat treatment. In addition, dispersion stability may be realized when the black metal oxide particles are doped into the carbon nanotube layer.

Accordingly, in the heat dissipation layer 190, the metal oxide is doped into the vertically aligned single-walled or double-walled carbon nanotube array, so that the heat dissipation layer 190 may serve as a buffer for cracks in the bank 170 and a color loss phenomenon in the bank 170 due to high heat. That is, through the heat dissipation layer 190, the color loss defect in the bank 170 may be prevented and reliability may be improved. In other words, heat generated from the LED 130 may be easily dissipated to the outside by using heat dissipation characteristics of the carbon nanotube layer of the heat dissipation layer 190.

In addition, in the display device 100 according to an example embodiment of the present disclosure, the reflection-reducing layer 180 is disposed between the bank 170 and the heat dissipation layer 190, so that an increase in external light reflection due to the metal oxide included in the heat dissipation layer 190 can be reduced.

The reflection-reducing layer 180 may be a layer having a reflectance that varies according to temperature. For example, the reflectance of the reflection-reducing layer 180 may decrease with increased temperature. The reflection-reducing layer 180 may include a base resin and a polymer that are dispersed in the base resin and having a reflectance that varies according to temperature.

An organic insulating layer having excellent heat resistance may be used as the base resin of the reflection-reducing layer 180. For example, the base resin may include one of polyimide resin, acryl resin, cardo resin, novolac resin, and siloxane resin.

The polymer of the reflection-reducing layer 180 may include poly(N-isopropylacrylamide) (PNIPAM), which is a polymer that changes a shape of itself in response to an external temperature stimulus. In the case of PNIPAM, which is a temperature-variable material, it may function as a haze layer at a driving temperature of the display device 100. That is, the polymer of the reflection-reducing layer 180 becomes hazy at a driving temperature of the display device 100 rather than at room temperature, thereby leading to a decrease in reflectance of the reflection-reducing layer 180, so that external light reflection at the time of driving the display device 100 may be reduced. For example, room temperature may be in a range of about 15° C. to about 25° C., and the driving temperature may be greater than 25° C., such as greater than 30° C., greater than 40° C., or greater than 50° C. For example, the reflection-reducing layer 180 may have haze less than about 10% at or near room temperature, and may have haze greater than about 50% at the driving temperature, such as greater than about 70%, greater than about 85% or another suitable range. The haze may present as anisotropic light scattering, which reduces reflectivity of the reflection-reducing layer 180.

Meanwhile, referring to FIG. 2, the planarization layers 116 and 117, the bank 170, the reflection-reducing layer 180, and the heat dissipation layer 190 described above may also be disposed in the non-active area NA. That is, in the non-active area NA, the planarization layers 116 and 117, the bank 170, the reflection-reducing layer 180, and the heat dissipation layer 190 may be sequentially stacked.

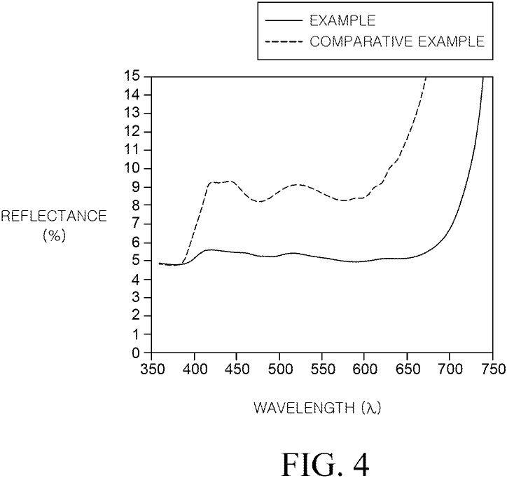

Hereinafter, FIG. 4 is referred to confirm an effect of reducing external light reflection by the reflection-reducing layer 180.

FIG. 4 is a graph for external light reflectances of display devices according to Comparative Example and Example of the present disclosure. The Example is the display device 100 described with reference to FIGS. 1 to 3, and the Comparative Example is a case in which the reflection-reducing layer 180 is omitted from the display device 100 described with reference to FIGS. 1 to 3.

Referring to FIG. 4, in the Comparative Example, since the reflection-reducing layer 180 is not used therein, a reflectance thereof is greater than that of the display device 100 according to the Example of the present disclosure in all wavelength bands. However, in the display device 100 according to the Example of the present disclosure, as the reflection-reducing layer 180 is added, external light reflection can be relatively reduced.

The example embodiments of the present disclosure can also be described as follows:

According to an aspect of the present disclosure, there is provided a display device. The display device comprises a first substrate including an active area including a plurality of pixels and a non-active area adjacent the active area; a plurality of LEDs disposed in the plurality of pixels on the first substrate; a planarization layer disposed to surround the plurality of LEDs on at least four sides; a bank disposed on the planarization layer and including a black material; a reflection-reducing layer disposed on the bank and having a reflectance that varies according to temperature thereof; and a heat dissipation layer disposed on the reflection-reducing layer.

The reflectance of the reflection-reducing layer may be lower at a driving temperature of the display device than at room temperature.

The reflection-reducing layer may function as a haze layer at the driving temperature of the display device.

The reflection-reducing layer include a base resin and a polymer dispersed in the base resin and having a reflectance varying according to temperature.

The base resin may include one of polyimide resin, acryl resin, cardo resin, novolac resin, and siloxane resin.

The polymer may include poly(N-isopropylacrylamide) (PNIPAM).

The heat dissipation layer may include a vertically aligned carbon nanotube (CNT) layer and metal oxide particles doped in the carbon nanotube layer.

The heat dissipation layer may further include carbon black particles, a binder, and a photosensitizer.

The binder may include an alkali-developable binder or a silicon-based binder.

The photosensitizer may include an oxime-based compound or a benzophenone-based compound.

The planarization layer may extend to the non-active area, and the bank, the reflection-reducing layer, and the heat dissipation layer may be sequentially stacked on the planarization layer in the non-active area.

The display device may further comprises a signal line disposed on the first substrate; a second substrate disposed under the first substrate; a signal link line disposed under the second substrate; and a side line disposed on side surfaces of the first substrate and the second substrate to connect the signal line and the signal link line.

The side line may be a line in which a conductive paste is cured.

Although the example embodiments of the present disclosure have been described in detail with reference to the accompanying drawings, the present disclosure is not limited thereto and may be embodied in many different forms without departing from the technical concept of the present disclosure. Therefore, the example embodiments of the present disclosure are provided for illustrative purposes only but not intended to limit the technical concept of the present disclosure. The scope of the technical concept of the present disclosure is not limited thereto. Therefore, it should be understood that the above-described example embodiments are illustrative in all aspects and do not limit the present disclosure. The protective scope of the present disclosure should be construed based on the following claims, and all the technical concepts in the equivalent scope thereof should be construed as falling within the scope of the present disclosure.

The various embodiments described above can be combined to provide further embodiments. All of the U.S. patents, U.S. patent application publications, U.S. patent applications, foreign patents, foreign patent applications and non-patent publications referred to in this specification and/or listed in the Application Data Sheet are incorporated herein by reference, in their entirety. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display device, comprising:
a first substrate including an active area including a plurality of pixels and a non-active area adjacent the active area;
a plurality of light-emitting diodes disposed in the plurality of pixels on the first substrate;
a planarization layer disposed to surround the plurality of light-emitting diodes on at least four sides;
a bank disposed on the planarization layer and including a black material;
a reflection-reducing layer disposed on the bank and having a reflectance that varies according to temperature thereof; and
a heat dissipation layer disposed on the reflection-reducing layer.

2. The display device of claim 1, wherein the reflectance of the reflection-reducing layer is lower at a driving temperature of the display device than at room temperature.

3. The display device of claim 2, wherein the reflection-reducing layer functions as a haze layer at the driving temperature of the display device.

4. The display device of claim 2, wherein the reflection-reducing layer includes a base resin and a polymer dispersed in the base resin and having a reflectance varying according to temperature.

5. The display device of claim 4, wherein the base resin includes one of polyimide resin, acryl resin, cardo resin, novolac resin, and siloxane resin.

6. The display device of claim 4, wherein the polymer includes poly(N-isopropylacrylamide) (PNIPAM).

7. The display device of claim 1, wherein the heat dissipation layer includes a vertically aligned carbon nanotube (CNT) layer and metal oxide particles doped in the carbon nanotube layer.

8. The display device of claim 7, wherein the heat dissipation layer further includes carbon black particles, a binder, and a photosensitizer.

9. The display device of claim 8, wherein the binder includes an alkali-developable binder or a silicon-based binder.

10. The display device of claim 8, wherein the photosensitizer includes an oxime-based compound or a benzophenone-based compound.

11. The display device of claim 1, wherein the planarization layer extends to the non-active area, and
the bank, the reflection-reducing layer, and the heat dissipation layer are sequentially stacked on the planarization layer in the non-active area.

12. The display device of claim 1, further comprising:
a signal line disposed on the first substrate;
a second substrate disposed under the first substrate;
a signal link line disposed under the second substrate; and
a side line disposed on side surfaces of the first substrate and the second substrate to connect the signal line and the signal link line.

13. The display device of claim 12, wherein the side line is a line in which a conductive paste is cured.

14. A display device, comprising:
a substrate;
a plurality of pixels on the substrate;
a plurality of light-emitting diodes disposed in the plurality of pixels;
a planarization layer adjacent to the plurality of light-emitting diodes;
a bank disposed on the planarization layer;
a first layer disposed on the bank and having reflectance that is lower at a driving temperature of the display device than at room temperature; and
a second layer disposed on the first layer, the second layer including a vertically aligned carbon nanotube layer doped with metal oxide particles.

15. The display device of claim 14, wherein the first layer has haze that is higher at the driving temperature than at the room temperature.

16. The display device of claim 14, wherein the metal oxide particles include black titanium oxide, black iron oxide or a combination thereof.

17. The display device of claim 14, wherein the bank has a plurality of openings that expose the plurality of light-emitting diodes, and the bank absorbs light in a range of about 380 nanometers to about 700 nanometers.

18. A display device, comprising:
a substrate;
a plurality of pixels on the substrate;
a plurality of light-emitting diodes disposed in the plurality of pixels;
a planarization layer adjacent to the plurality of light-emitting diodes;
a bank disposed on the planarization layer, the bank absorbing light in a range of about 380 nanometers to about 700 nanometers; and
a vertically aligned carbon nanotube layer disposed on the bank.

19. The display device of claim 18, wherein:
the substrate includes an active area and a non-active area adjacent the active area, the plurality of pixels being in the active area; and
the carbon nanotube layer is on the bank in the active area and in the non-active area.

20. The display device of claim 19, further comprising:
a signal line disposed on the substrate;
a second substrate disposed under the substrate;
a signal link line disposed under the second substrate;
an insulating layer adjacent sidewalls of the substrate and the second substrate; and
a side line disposed on the sidewalls of the substrate and the second substrate to connect the signal line to the signal link line, the side line including a conductive paste that is between the insulating layer and the sidewalls of the substrate and the second substrate.
